(19) United States
(12) Patent Application Publication
(10) Pub. No.: US 2022/0376034 A1
(43) Pub. Date: Nov. 24, 2022

(54) SEMICONDUCTOR PACKAGE STRUCTURE AND METHOD FOR FORMING THE SAME

(71) Applicant: TAIWAN SEMICONDUCTOR MANUFACTURING COMPANY LTD., HSINCHU (TW)

(72) Inventors: YANG-CHE CHEN, HSIN-CHU CITY (TW); CHEN-HUA LIN, YUNLIN COUNTY (TW); VICTOR CHIANG LIANG, HSINCHU CITY (TW); HUANG-WEN TSENG, HSINCHU COUNTY (TW); CHWEN-MING LIU, HSINCHU (TW)

(21) Appl. No.: 17/321,158

(22) Filed: May 14, 2021

(51) Int. Cl. H01L 49/02; H01L 23/31; H01L 23/532; H01L 21/768; H01L 27/06; H01L 23/538

(52) U.S. Cl. CPC H01L 28/10; H01L 23/31; H01L 23/532; H01L 21/76802; H01L 27/0688; H01L 23/5384

(57) ABSTRACT

A semiconductor package structure includes a magnetic core, a molding surrounding the magnetic core, a first RDL under the magnetic core, a second RDL over the magnetic core, and a plurality of through vi as in the molding. The magnetic core has a first core surface and a second core surface opposite to the first core surface, The molding has a first molding surface and a second molding surface opposite to the first molding surface. The first molding surface is substantially aligned with the first core surface, and the second molding surface is substantially aligned with the second core surface. The first RDL includes a plurality of first conductive lines. The second RDL includes a plurality of second conductive lines. The through vias are coupled to the first conductive lines and the second conductive lines to form a coil surrounding the magnetic core.

### BACKGROUND

The semiconductor industry has experienced rapid growth, due in part to ongoing improvements in the integration density of a variety of electronic components (e.g., transistors, diodes, resistors, capacitors, etc.). For the most part, improvements in integration density have resulted from iterative reduction of minimum feature size, which allows more components to be integrated into a given area. As the demand for smaller electronic devices has increased, a need for more space-efficient and creative packaging techniques for semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a semiconductor package structure according to aspects of the present disclosure.

FIG. 2 is a cross-sectional view illustrating a semiconductor package structure according to aspects of the present disclosure.

FIG. 3 is a cross-sectional view illustrating a semiconductor package structure according to aspects of the present disclosure.

FIG. 4 is a perspective view illustrating a 3D solenoid inductor shown in FIGS. 1, and 3 according to aspects of the present disclosure.

FIG. 5 is a flowchart representing a method for forming a semiconductor package structure according to aspects of the present disclosure,

FIGS. 6A to 6G are schematic drawings illustrating stages of a method for forming a package semiconductor structure according to aspects of the present disclosure.

FIGS. 7A to 7G are schematic drawings illustrating stages of a method fir forming a package semiconductor structure according to aspects of the present disclosure.

### DETAILED DESCRIPTION

The following disclosure provides many different embodiments, or examples, for implementing different features of the provided subject matter, Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. in addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; rather, the scope of the disclosure shall be defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques, Ranges can he expressed herein as being from one endpoint to another endpoint or between two endpoints. All ranges disclosed herein are inclusive of the endpoints, unless specified otherwise.

Other features and processes may also be included. For example, testing structures may he included to aid in the verification testing of 3D packaging or 3DIC devices. The testing structures may include, for example, test pads formed in a redistribution layer or on a substrate that allows the testing of the 3D packaging or 3 DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

An inductor is a passive electrical component that stores energy in its magnetic field. Inductors are used extensively in analog circuits, signal processing systems, and wireless communication systems. Further, inductors in conjunction with other electrical components may provide further functions. For example, inductors, capacitors and other components may form circuits that can filter out signal frequencies. Two or more inductors with coupled magnetic flux form a transformer, which is a power converter that transfers electrical energy from one circuit to another,

In some comparative embodiments, inductors may be of a planar pattern formed in a redistribution layer (RDL) of a semiconductor package structure. The planar inductor may show good quality with a Q value greater than about 51. The Q value is a parameter that indicates the quality of an inductor, and a higher Q value means lower energy loss and better suitability for use as a high-frequency inductor. However, such planar inductor may be an air-core inductor. As a result, the inductance may be lower than 3 nanohenries (nH). This weakness limits its applications to RF systems in gigahertz (GHz) frequency range.

The present disclosure therefore provides a semiconductor package structure including a three-dimensional (3D) solenoid inductor and a method for forming the same. The 3D solenoid inductor may include a permanent magnetic core such that a greater inductance is obtained.

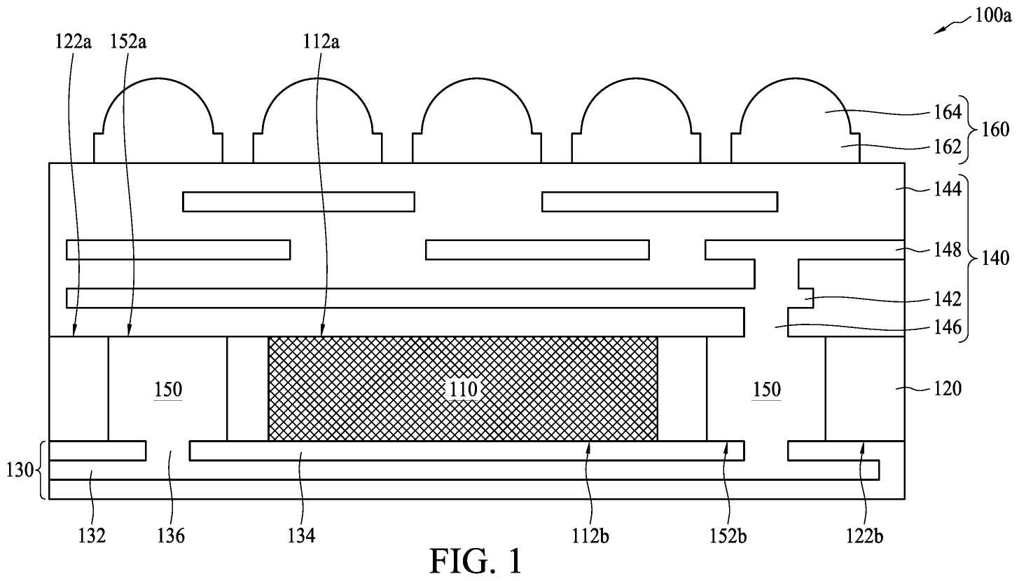

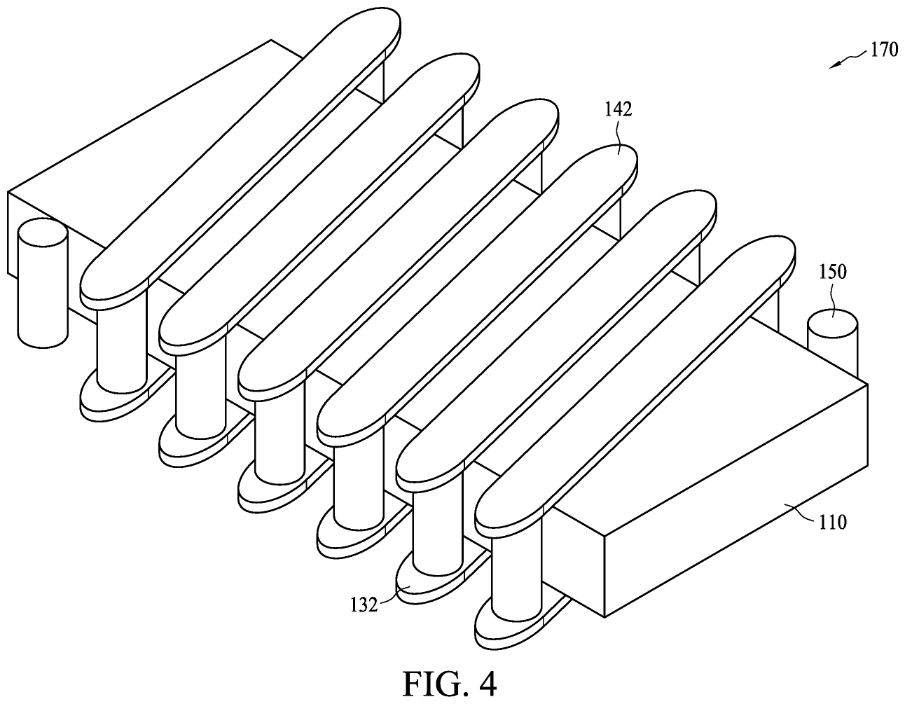

Please refer to FIGS. 1 and 4, wherein FIG. 1 is a cross-sectional view illustrating a semiconductor package structure 100a, and FIG. 4 is a perspective view illustrating a 3D solenoid inductor shown in FIG. 1 according to aspects of the present disclosure. As shown in FIG. 1, the semiconductor package structure 100a includes a magnetic core 110. The magnetic core 110 has a first core surface 112a and a second core surface 112b opposite to the first core surface 112a. In some embodiments, the magnetic core 110 may be a permanent magnetic core, but the disclosure is not limited thereto.

The semiconductor package structure 100a includes a molding 120. The molding 120 has a first molding surface 122a and a second molding surface 122b opposite to the first molding surface 122a. Further, the first molding surface 122a is substantially aligned with (i.e., coplanar with) the first core surface 112a, and the second molding surface 122b is substantially (i.e., coplanar with) the second core surface 112b, as shown in FIG. 1. Additionally, a thickness of the magnetic core 110 is substantially same as a thickness of the molding 120, In some embodiments, the molding 120 may include resins such as epoxy, but the disclosure is not limited thereto. In some embodiments, the molding 120 may include one or more catalysts to accelerate curing of the resins. In some embodiments, the molding 120 may include other materials, such as flame retardants, adhesion promoters, ion traps, and/or stress relievers.

Additionally, the magnetic core 110 has a length, a width and a thickness. The length, the width and the thickness of the magnetic core 110 may be determined by, e.g., design requirements, size of the semiconductor package 100a, and available space in the molding 120.

The semiconductor package structure 100a further include a first redistribution layer (RDL) 130 and a second RDL 140. As shown in FIG. 1, the magnetic core 110 and the molding 120 are disposed between the first and second RDLs 130 and 140. In some embodiments, the first RDL 130 is under the magnetic core 110 and the molding 120, while the second RDL 140 is over the magnetic core 110 and the molding 120.

The first RDL 130 includes a plurality of first conductive lines 132 disposed in a dielectric layer 134. It should be noted that the first conductive lines 132 are in a same level, as shown in FIG. 4, Thus, bottom surfaces of the first conductive lines 132 are in a same level, or aligned with each other. Additionally, top surfaces of the first conductive lines 132 are in a same level, or aligned with each other. In some embodiments, the first RDL 130 may include other conductive lines disposed in the dielectric layer 134, and such conductive lines may form various electrical connections, though not shown. In some embodiments, the first conductive lines 132 include one or more conductive materials, such as tungsten (W), aluminum (Al), copper (Cu), gold (Au), silver (Ag), or platinum (Pt), but the disclosure is not limited thereto. In some embodiments, the dielectric layer 134 may be a multi-layered structure, though not shown. In some embodiments, the dielectric layer 134 may include a polymer such as polybenzoxazole (PBG), polyimide, benzocyclobutene (BCB) or the like. In other embodiments, the dielectric layer 134 may include silicon nitride, silicon oxide, phosphosilicate glass (PSG), borosilicate glass (BSG), boron-doped phosphsilicate glass (BPSG), or the like. Further, the first RDL 130 includes a plurality of connecting vias 136 coupled to the first conductive lines 132, as shown in FIG. 1.

The second RDL 140 may include a plurality of second conductive lines 142 disposed in a dielectric layer 144. It should be noted that the second conductive lines 142 are in a same level, as shown in FIG. 4. Thus, bottom surfaces of the second conductive lines 142 are in a same level, or aligned with each other. Additionally, top surfaces of the second conductive lines 142 are in a same level, or aligned with each other. In some embodiments, the second RDL 140 may include other overlying conductive lines 148 disposed in the dielectric layer 144. Further, the overlying conductive lines 148 may be formed over the second conductive lines 142, as shown in FIG. 1. Such overlying conductive lines 148 may form various electrical connections, though not shown. In such embodiments, the second conductive lines 142 may be lowest conductive lines in the second RDL 140, but the disclosure is not limited thereto, In some embodiments, underlying conductive lines may be disposed in the second RDL 140, though not shown. in some embodiments, the overlying conductive lines 148 may be electrically connected to the second conductive lines 142. Alternatively, the overlying conductive lines 148 may be electrically isolated from the second conductive lines 142. Electrical connections of the second conductive lines 142 and the overlying conductive lines 148 may vary in accordance with different product designs.

In some embodiments, the second conductive lines 142 and the overlying conductive lines 148 may include a same material. In such embodiments, the second conductive lines 142 and the overlying conductive lines 148 may include one or more conductive materials, such as W, Al, Cu, Au, Ag, or Pt, but the disclosure is not limited thereto. In some embodiments, the dielectric layer 144 may be a multi-layered structure, though not shown. In some embodiments, the dielectric layer 144 may include polymer such as PBO, polyimide, BCB or the like. In other embodiments, the dielectric layer 144 may include silicon nitride, silicon oxide, PSG, BSG, BPSG, or the like. Further, the second RDL 140 includes a plurality of connecting vias 146 coupled to the second conductive lines 142, as shown in FIG. 1.

Still referring to FIG. 1, the semiconductor package structure 100a further includes a plurality of through vias 150 disposed in the molding 120. In some embodiments, the through vias 150 may be referred to as through molding vias (TMVs) or through insulator vias (TIVs). In some embodiments, each of the through vias 150 has a first via surface 152a and a second via surface 152b opposite to the first via surface 152a. In some embodiments, the first via surface 152a is substantially aligned with (i.e., coplanar with) the first core surface 112a and the first molding surface 122a, while the second via surface 152b is substantially aligned with (i.e., coplanar with) the second core surface 112b and the second molding surface 122b. Additionally, heights of the through vias 150 are substantially same as the thickness of the magnetic core 110 and the thickness of the molding 120. The through vias 150 may include conductive materials such as Cu, Ti, W, Al, or the like.

In some embodiments, the through vias 150 are coupled to the first conductive lines 132 and the second conductive lines 142 to form a coil surrounding or encircling the magnetic coil 110, as shown in FIG. 4. The first conductive lines 132 (i.e., the top surfaces of the first conductive lines 132) are separated from the magnetic core 110 by the dielectric layer 134, the second conductive lines 142 (i.e., the bottom surfaces of the second conductive lines 142) are separated from the magnetic core 110 by the dielectric layer 144, and the through vias 150 (i.e, sidewalls of the through vias 150) are separated from the magnetic core 110 by the molding 120.

In some embodiments, the semiconductor package structure 100a further includes a plurality of external connectors 160 disposed over the second RDL 140. In some embodiments, the external connectors 160 are disposed on an exterior side of the second RDL 140. In some embodiments, the external connector 160 may include a pad 162 and a conductive connector 164. In some embodiments, the pad 162 may be referred to as an under bump metallurgy (UBM). In some embodiments, the pads 162 may include conductive material such as Cu, Ti, W, Al or the like. In some embodiments, the conductive connector 164 may be a BGA connector, a solder ball, a metal pillar, a controlled collapse chip connection (C4) bump, a micro bump, electroless nickel-electroless palladium-immersion gold technique (ENEPIG) formed bump, or the like, In some embodiments, the conductive connectors 164 may include conductive material such as solder, Cu, Au, Ag, nickel (Ni), palladium (Pd), tin (Sn), or the like.

Referring to FIGS. 1 and 4, accordingly, the semiconductor package structure 100a includes a three-dimensional (3D) solenoid inductor 170 formed by the magnetic core 110 encircled by the coil formed by the first conductive lines 132, the second conductive lines 142 and the through vias 150. Additionally, the 3D solenoid inductor 170 is a surface mounted device (SMD) inductor. By disposing the magnetic core 110 along an axis of the coil, an inductor value may be changed according to the permeability of the magnetic core 110. As the inductance changes, the Q value of the 3D solenoid inductor 170 also changes. The relationship be derived from the following equations:

$$L = \frac{{μ}_{0} {N}^{2} a}{l}$$

$$Q = \frac{\overline{ω} L}{R}$$

Here L is an inductance of the 3D solenoid inductor 170, μ0 is a permeability of a free space, N is a number of coils, A is an area of the cross-section of the coil in square meters, l is a length of coil in meters, Q is a quality factor, w is frequency, and R is resistance, In some embodiments, the inductance L may be increased by using the magnetic core 110 with a large permeability, thus increasing the Q value.

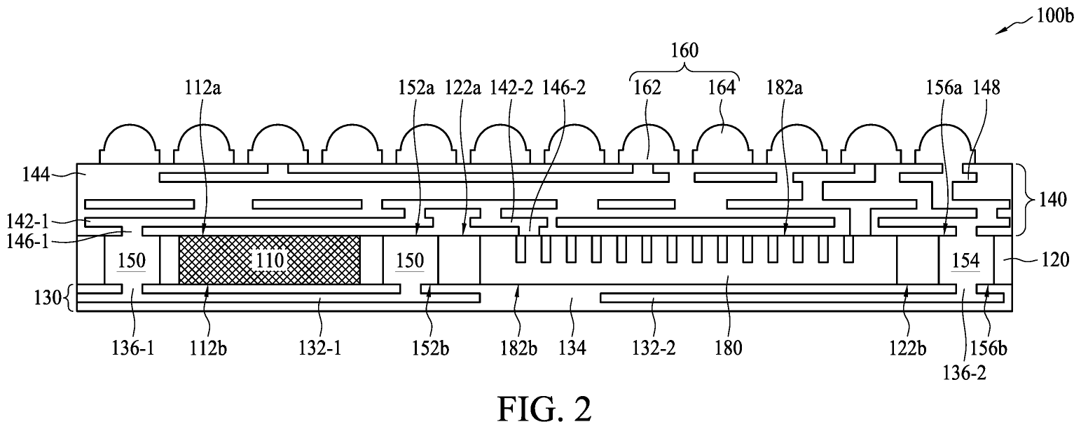

Please refer to FIGS. 2 and 4, wherein FIG. 2 is a cross-sectional view illustrating a semiconductor package structure 100b, and FIG. 4 is a perspective view illustrating a 3D solenoid inductor shown in FIG. 2 according to aspects of the present disclosure. It should be noted that same elements in FIGS. 1 and 2 may include same materials and are indicated by same numerals; therefore, repeated descriptions are omitted for brevity.

The semiconductor package structure 100b includes a die 180 and a magnetic core 110 disposed adjacent to the die 180. As mentioned above, the magnetic core 110 may be a permanent magnetic core, but the disclosure is not limited thereto. In some embodiments, the die 180 may include an integrated circuit (IC) die. The IC die may he a logic die (e.g., a central processing unit (CPU) die or chip, a microcontroller die, etc.), a memory die (e.g., a. dynamic random access memory (DRAM) die, a static random access memory (SRAM) die, etc.), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die), a front-end die (e.g., an analog front-end (AFE) die), a bio chip, an energy harvesting chip, the like, or a combination thereof. In some embodiments, the die 180 may include passive devices. In such embodiments, the die 180 may be a zero-inductance integrated passive device (ZLIPD) die, but the disclosure is not limited thereto. As mentioned above, the magnetic core 110 includes a first core surface 112a and a second core surface 112b opposite to the first core surface 112a. In some embodiments, the die 180 has a first die surface 182a and a second die surface 182b opposite to the first die surface 182a. Further, the first die surface 182a may be an active surface of the die 180. As shown in FIG. 2, the first core surface 112a is substantially aligned with (i.e., coplanar with) the first die surface 182a, and the second core surface 112b is substantially aligned with (i.e., coplanar with) the second die surface 182b. Additionally, a thickness of the magnetic core 110 and a thickness of the die 180 are same.

The semiconductor package structure 100b includes a molding 120. The molding 120 surrounds the magnetic core 110 and the die 180. As mentioned above, the molding 120 has a first molding surface 122a and a second molding surface 122b opposite to the first molding surface 122a, Further, the first molding surface 122a is substantially aligned with (i.e., coplanar with) the first core surface 112a and the first die surface 182a, and the second molding surface 122b is substantially aligned with (i.e., coplanar with) the second core surface 112b and the second die surface 182b, as shown in FIG. 2. Additionally, a thickness of the molding 120 is substantially same as the thickness of the magnetic core 110 and the thickness of the die 180.

The semiconductor package structure 100b further include a first RDL 130 and a second RDL 140. As shown in FIG. 2, the magnetic core 110, the die 180 and the molding 120 are disposed between the first and second RDLs 130 and 140. In some embodiments, the first RDL 130 is under the die 180, the magnetic core 110 and the molding 120, while the second RDL 140 is over the die 180, the magnetic core 110 and the molding 120. In some embodiments, the first die surface 182a is the active surface, thus the first RDL 130 may be referred to as a back-side RDL, and the second RDL 140 may be referred to as a front-side RDL. The back-side and front-side RDLs 130 and 140 may extend beyond a boundary of the die 180, thereby enabling fan-out of the die 180 and allowing connection with other packages or components in areas outside the boundary of the die 180. Therefore, the semiconductor package structure 100b is also referred to as an integrated fan-out (InFO) package.

As shown in FIG. 2, the first RDL 130 includes a plurality of conductive lines 132-1 disposed in a dielectric layer 134. It should be noted that the conductive lines 132-1 are in a same level, as shown in FIG. 4. Thus, bottom surfaces of the conductive lines 132-1 are in a same level, or aligned with each other. Additionally, top surfaces of the conductive lines 132-1 are in a same level, or aligned with each other. In some embodiments, the first RDL 130 may include other conductive lines disposed in the dielectric layer 134, and such conductive lines may form various electrical connections, though not shown. In some embodiments, the dielectric layer 134 may be a multi-layered structure. Further, the first RDL 130 includes a plurality of connecting vias 136-1 coupled to the conductive lines 132-1, as shown in FIG. 2.

The second RDL 140 may include a plurality of conductive lines 142-1 disposed in a dielectric layer 144. It should be noted that the conductive lines 142-1 are in a same level, as shown in FIG. 2. Thus, bottom surfaces of the conductive lines 142-1 are in a same level, or aligned with each other. Additionally, top surfaces of the conductive lines 142-1 are in a same level, or aligned with each other. In some embodiments, the second RDL 140 may include other overlying conductive lines 148 disposed in the dielectric layer 144. Further, the overlying conductive lines 148 may be formed over the conductive lines 1.42-1, as shown in FIG. 2. Such overlying conductive lines 148 may form various electrical connections, though not shown. In such embodiments, the conductive lines 142-1 may be lowest conductive lines in the second RDL 140, but the disclosure is not limited thereto. In some embodiments, underlying conductive lines may be disposed in the second RDL 140, though not shown. In some embodiments, the overlying conductive lines 148 may be electrically connected to the conductive lines 142-1. Alternatively, the overlying conductive lines 148 may be electrically isolated from the conductive lines 142-1. Electrical connections of the conductive lines 142-1 and the overlying conductive lines 148 may vary in accordance with different product requirements. In some embodiments, the dielectric layer 144 may be a multi-layered structure, though not shown. Further, the second RDL 140 includes a plurality of connecting vias 146-1 coupled to the second conductive lines 142-1, as shown in FIG. 2.

It should be noted that the conductive lines 132-1 are disposed under the magnetic core 110, and the conductive lines 142-1 are disposed over the magnetic core 110, as shown in FIGS. 2 and 4. Thus, the magnetic core 110 overlaps a portion of each conductive line 132-1 and a portion of each conductive line 142-1.

Still referring to FIG. 2, the semiconductor package structure 100b further includes a plurality of through vias 150 disposed in the molding 120. As mentioned above, the through vias 150 may be referred to as TMVs or TIVs. In some embodiments, each of the through vias 150 has a first via surface 152a and a second via surface 152b opposite to the first via surface 152a. In some embodiments, the first via surface 152a is substantially aligned with (i.e., coplanar with) the first die surface 182a, the first core surface 112a and the first molding surface 122a, while the second via surface 152b is substantially aligned with (i.e., coplanar with) the second die surface 182b, the second core surface 112b and the second molding surface 122b. Additionally, a height of the through vias 150 is substantially same as the thickness of the die 180, the thickness of the magnetic core 110 and the thickness of the molding 120.

In some embodiments, the through vias 150 are coupled to the conductive lines 132-1 and the conductive lines 142-1 to form a coil surrounding the magnetic core 110, as shown in FIG. 4. Further, the conductive lines 132-1 (i.e., top surfaces of the conductive lines 132-1) are separated from the magnetic core 110 by the dielectric layer 134, the conductive lines 142-1 (i.e., the bottom surfaces of the conductive lines 142-1) are separated from the magnetic core 110 by the dielectric layer 144, and the through vias 150 (i,e, sidewalls of the through vias 150) are separated from the magnetic core 110 by the molding 120.

In some embodiments, the first RDL 130 includes one or more conductive lines 132-2 disposed in the dielectric layer 134. It should be noted that the conductive lines 132-1 and the conductive lines 132-2 are in a same level. Thus, bottom surfaces of the conductive lines 132-2 and the bottom surfaces of the conductive lines 132-1 are in a same level, or aligned with each other. Additionally, top surfaces of the conductive lines 132-2 and the top surfaces of the conductive lines 132-1 are in a same level, or aligned with each other. Further, the first RDL 130 includes a plurality of connecting vias 136-2 coupled to the conductive lines 132-2, as shown in FIG. 2.

The second RDL 140 may include a plurality of conductive lines 142-2 disposed in the dielectric layer 144. It should be noted that the conductive lines 142-1 and the conductive lines 142-2 are in a same level, as shown in FIG. 2. Thus, bottom surfaces of the conductive lines 142-2 and the bottom surfaces of the conductive lines 142-1 are in a same level, or aligned with each other. Additionally, top surfaces of the conductive lines 142-2 and the top surfaces of the conductive lines 142-1 are in a same level, or aligned with each other. Further, the overlying conductive lines 148 may be formed over the conductive lines 142-2, as shown in FIG. 2. The conductive lines 142-2 and the overlying conductive lines 148 may form various electrical connections, though not shown. In such embodiments, the conductive lines 142 may be lowest conductive lines in the second RDL 140, but the disclosure is not limited thereto. Electrical connections of the conductive lines 142-2 and the overlying conductive lines 148 may vary in accordance with different product designs. Further, the second RDL 140 includes a plurality of connecting vias 146-2 coupling the conductive lines 142-2 to the die 180, as shown in FIG. 2.

Still referring to FIG. 2, the semiconductor package structure 100b further includes one or more through vias 154 disposed in the molding 120. As mentioned above, the through via 154 may be referred to as a TMV or a TIV. In some embodiments, each of the through vias 154 has a first via surface 156a and a second via surface 156b opposite to the first via surface 156a. In some embodiments, the first via surface 156a is substantially aligned with (i.e., coplanar with) the first die surface 182a and the first molding surface 122a, while the second via surface 156b is substantially aligned with (i.e., coplanar with) the second die surface 182b and the second molding surface 122b, Additionally, a height of the through via 154 is substantially same as the thickness of the die 180 and the thickness of the molding 120. In some embodiments, the through via 154 is coupled to the conductive lines 132-2 and the conductive lines 142-2. In some embodiments, the through via 154 may be electrically connected to the conductive lines 142-2 and the overlying conductive lines 148.

As mentioned above, the conductive lines 132-1, the conductive lines 142-1 and the through vias 150 are coupled to form a coil surrounding the magnetic core 110. The coil and the magnetic core 110 form a 3D solenoid inductor 170. In some embodiments, the 3D solenoid inductor 170 is electrically isolated from the die 180. In some embodiments, the 3D solenoid 170 is electrically connected to the die 180, as shown in FIG. 2. In such embodiments, the coil of the 3D solenoid inductor 170 is electrically connected to the die 180 through the overlying conductive line 148, the conductive line 142-2 and the connecting via 146-2. Further, when the die 180 is a ZLIPD die, the electrically connected 3D solenoid inductor 170 and the die 180 form an inductance-capacitance (LC) tank.

In some embodiments, the semiconductor package structure 100b further includes a plurality of external connectors 160 disposed over the second RDL 140. As mentioned above, the external connectors 160 are disposed on an exterior side of the second RDL 140. In some embodiments, the external connector 160 may include a pad 162 and a conductive connector 164.

Referring to FIGS. 2 and 4, accordingly, the semiconductor package structure 100b includes 3D solenoid inductor 170 formed by the magnetic core 110 encircled by a coil formed by the conductive lines 132-1, the conductive lines 142-1 and the through vias 150. By disposing the magnetic core 110 along an axis of the coil, an inductor value may be changed according to the permeability of the magnetic core 110. As mentioned above, the inductance of the 3D solenoid inductor 170 may be increased by using the magnetic core 110 with a large permeability, thus increasing the Q value.

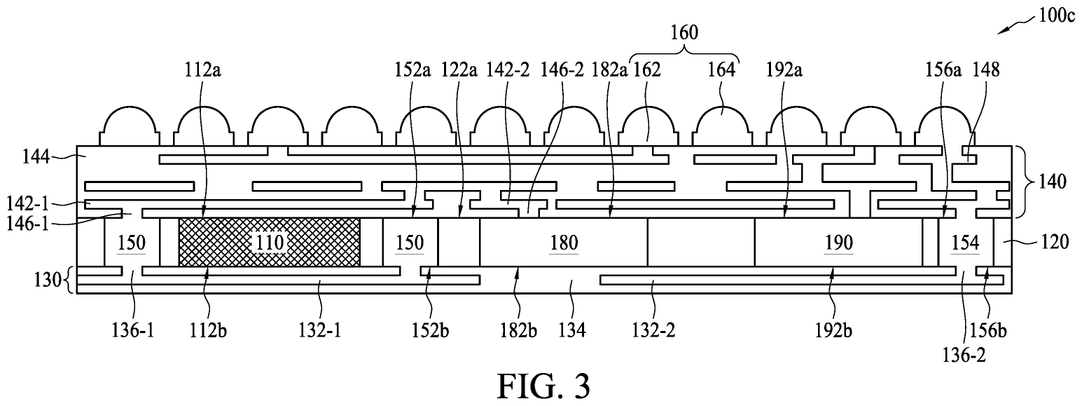

In some embodiments, the InFO package structure may include more than one die. Referring to FIGS. 3 and 4, in some embodiments, the semiconductor package structure 100c is provided, The semiconductor package structure 100c may include at least two dies 180 and 190. In some embodiments, the die 180, the die 190 and the magnetic core 110 are disposed in the molding 120. The die 190 may include a first die surface 192a and a second die surface 192b opposite to the first die surface 192a. In some embodiments, the first die surface 192a of the die 190 is substantially aligned with (i.e., coplanar with) the first die surface 182a of the die 180 and the first core surface 112a of the magnetic core 110. The second die surface 192b of the die 190 is substantially aligned with (i.e., coplanar with) the second die surface 182b of the die 180 and the second core surface 112b of the magnetic core 110. In other words, a thickness of the die 190 may be same as the thickness of the die 180 and the thickness of the magnetic core 110.

In some embodiments, the die 190 may be an IC die. The IC die may be a logic die, a memory die, a power management die, an RF die, a sensor die, a MEMS die, a signal processing die, a front-end die, a bio chip, an energy harvesting chip, the like, or a combination thereof.

In some embodiments, the die 190 may be electrically connected to the overlying conductive lines 148 of the second RDL 140. In some embodiments, the die 190 may be electrically connected to the external connector 160 through the second RDL 140. In some embodiments, the die 190 is electrically connected to the 3D solenoid inductor 170. Alternatively, the die 190 is electrically isolated from the 3D solenoid inductor 170. Additionally, the die 180 and the die 190 may be electrically connected to or isolated from each other. The electrical connections between the 3D solenoid inductor 170, the die 180 and the die 190 may vary in accordance with different product designs. Further, the dies 180 and 190 may be different dies for providing different functions. For example, in some embodiments, the die 180 may be a ZLIPD die, and the die 190 may be a power management IC (PMIC) die. In such embodiments, the 3D solenoid inductor 170, the ZLIPD die 180 and the PMIC die 190 form a voltage regulator.

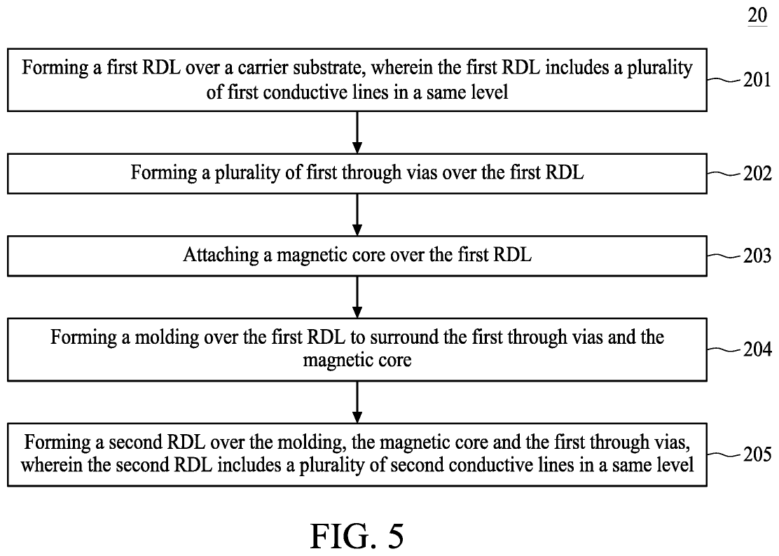

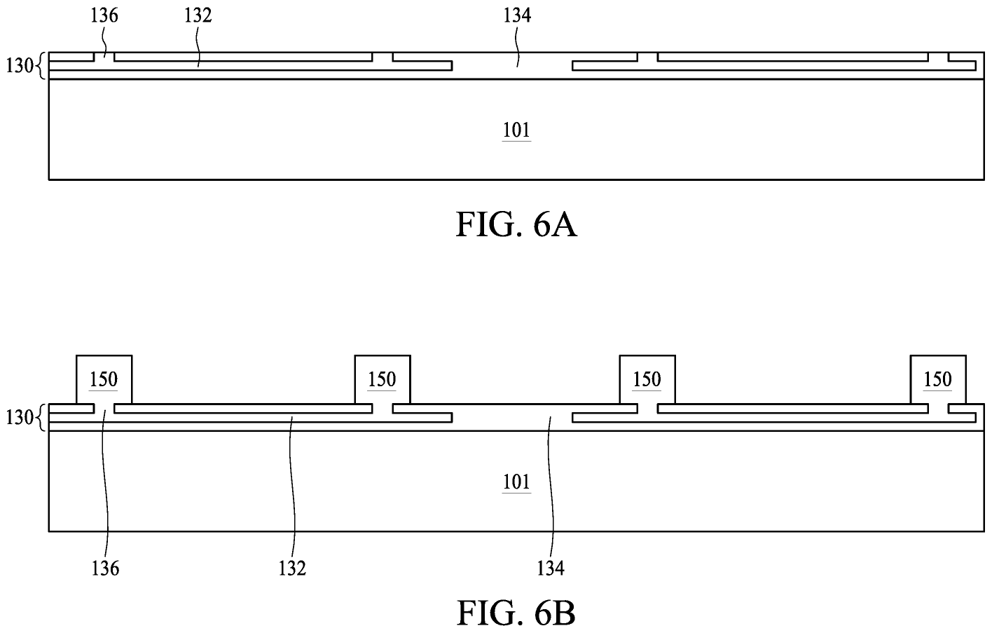

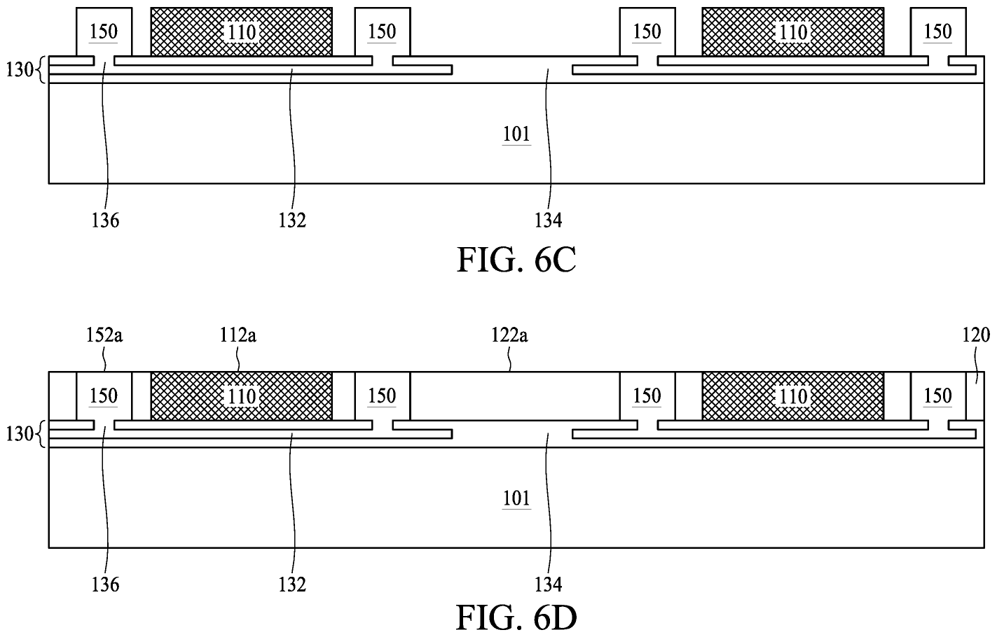

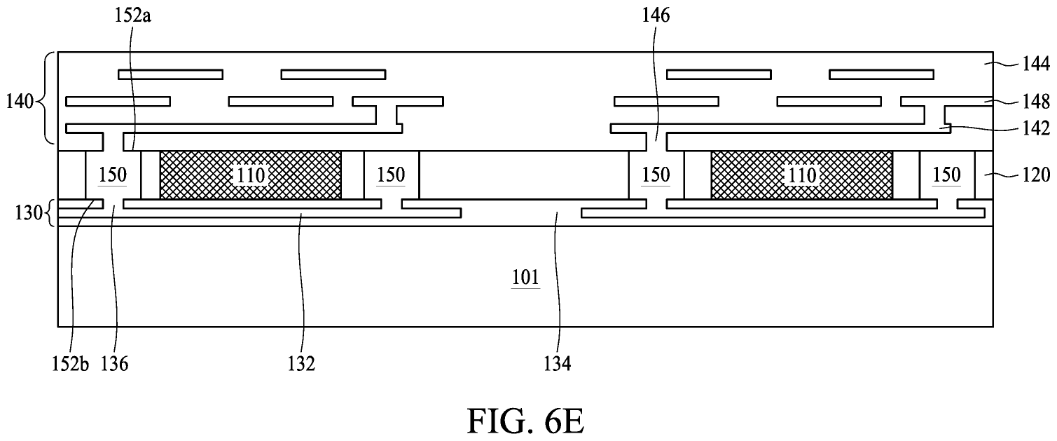

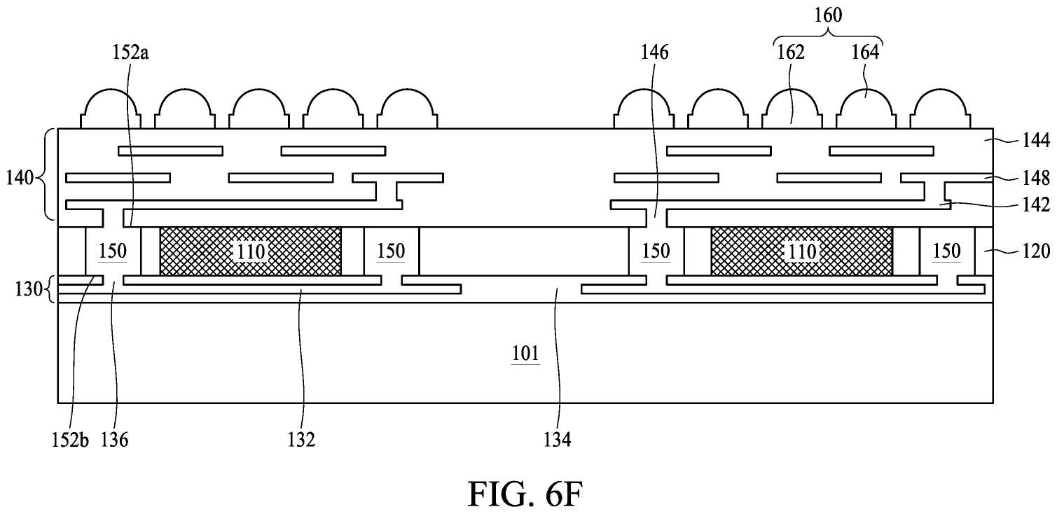

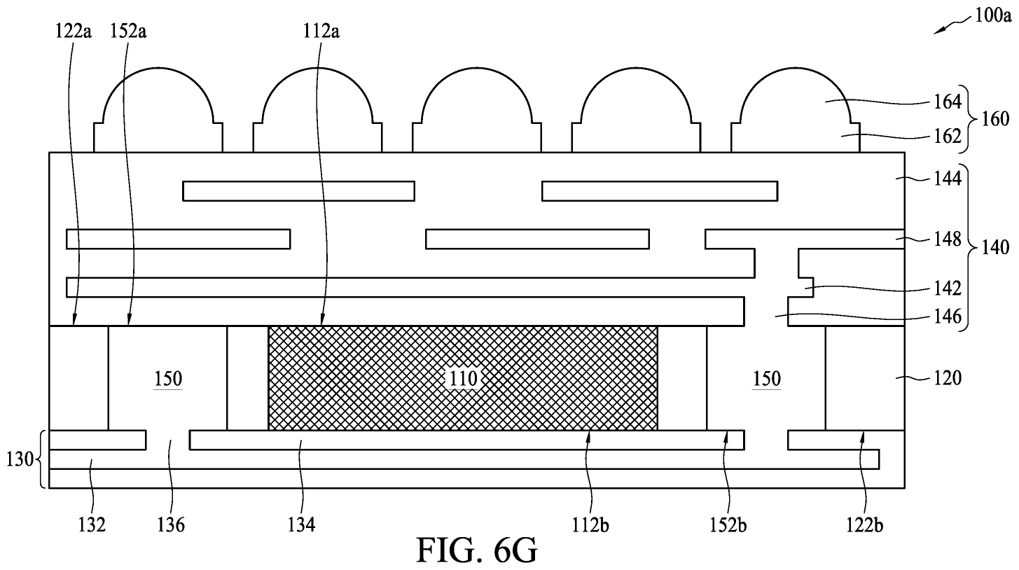

FIG. 5 is a flowchart representing a method for forming a semiconductor package structure 20 according to aspects of the present disclosure, and FIGS. 6A to 6G are schematic drawings illustrating stages of the method for forming a semiconductor package structure 20 according to aspects of the present disclosure. It should be noted that same elements in FIGS. 1 and 6A to 6G may include same materials and are indicated by the same numerals; therefore, repeated descriptions are omitted for brevity. The method 20 includes a number of operations (201, 202, 203, 204 and 205). The method 20 will be further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein.

Referring to FIG. 6A, in some embodiments, a first RDL 130 is formed on a carrier substrate 101 in operation 201. In some embodiments, the carrier substrate 101 is received, and a release layer (not shown) may be formed on the carrier substrate 101. In such embodiments, the first RDL 130 may be formed on the release layer. The carrier substrate 101 may be a glass carrier substrate, a ceramic carrier substrate, or the like. The release layer may be formed of a polymer-based material, which may be removed, along with the carrier substrate 101, from the overlying structure, which will be formed in subsequent operations. In some embodiments, the release layer may lose its adhesive property when heated, such as a light-to-heat-conversion (LTHC) release coating. In some embodiments, the release layer may be an ultra violet (UV) glue, which may be disposed as a liquid and cured, may be a film laminated onto the carrier substrate 101, or the like.

The first RDL 130 includes a plurality of first conductive lines 132 and a plurality of connecting vias 136 disposed in a multi-layered dielectric layer 134. In some embodiments, the first RDL 130 may be referred to as a back-side RDL. In some embodiments, the dielectric layer 134 is formed by any suitable deposition process, such as spin coating, chemical vapor deposition (CVD), laminating, the like, or a combination thereof As shown in FIG. 6A., the first RDL 130 may include one layer of the first conductive lines 132 and one layer of the connecting vias 136 in the multi-layered dielectric layer 134. However, in other embodiments, the first RDL 130 may include any number of layers of conductive lines and vias.

Referring to FIG. 6B, a plurality of through vias 150 are formed over the first RDL 130 in operation 202. In some embodiments, a seed layer (not shown) is formed over the first RDL 130. The seed layer may be a metal layer. The seed layer may be a single-layered structure or a multi-layered structure. For example, the seed layer may include a Ti sublayer and a Cu sublayer over the Ti sublayer. A patterned photoresist may be formed on the seed layer. The patterned photoresist includes openings that expose portions of the seed layer. A conductive material is then formed in the opening of the patterned photoresist on the exposed portions of the seed layer. In some embodiments, the conductive material may be formed by plating, such as electroless plating, or the like. in some embodiments, after the forming of the conductive material, the patterned photoresist and portions of the seed layer on which no conductive material is formed are removed. Accordingly, the through vias 150 are obtained as shown in FIG. 6B. In some embodiments, the through vias 150 are coupled to the first conductive lines 132 through the connecting vias 136.

Referring to FIG. 6C, in some embodiments, a magnetic core 110 is attached over the first RDL 130 in operation 203. In some embodiments, the magnetic core 110 is adhered to the first RDL 130 by an adhesive layer (not shown), but the disclosure is not limited thereto. The adhesive layer may be any suitable adhesive, epoxy, die attach film (DAF), or the like. In some embodiments, the magnetic core 110 is disposed in a place surrounded by the through vias 150, as shown in FIG. 6C.

Referring to FIG. 6D, in some embodiments, a molding 120 is formed over the first RDL 130 to surround the through vias 150 and the magnetic core 110 in operation 204. In some embodiments, the molding 120 may be applied by compression molding, transfer molding, or the like. In some embodiments, after applying and curing the molding 120, a grinding operation may he performed on the molding 120 to expose first via surfaces 152a of the through vias 150. In some embodiments, a first core surface 112a of the magnetic core 110 is also exposed after the grinding. In some embodiments, the first via surfaces 152a of the through vias 150, the first core surface 112a of the magnetic core 110, and a first molding surface 122a of the molding 120 are aligned with (i.e., coplanar with) each other after the grinding.

Referring to FIG. 6E, in some embodiments, a second RDL 140 is formed over the molding 120, the magnetic core 110 and the through vias 150 in operation 205. The second RDL 140 includes a plurality of second conductive lines 142 and a plurality of connecting vias 146 disposed in a multi-layered dielectric layer 144. In some embodiments, the second RDL 140 may be referred to as a front-side RDL. In some embodiments, the dielectric layer 144 is formed by any suitable deposition process, such as spin coating, CVD, laminating, the like, or a combination thereof. As shown in FIG. 6E, the second RDL 140 may include one layer of the second conductive lines 142 and one layer of the connecting vias 146 in the multi-layered dielectric layer 144. Further, the second RDL 140 may include overlying conductive lines 148 and connecting vias electrically connected to or electrically isolated from the second conductive lines 142. The second conductive lines 142 are electrically connected to the through vias 150 by the connecting vias 146.

Referring to FIG. 6F, in some embodiments, a plurality of external connectors 160 are formed over the second RDL 140. The external connectors 160 are formed on an exterior side of the second RDL 140. In some embodiments, each external connector 160 includes a pad 162 and a conductive connector 164 over the pad 162.

Referring to FIG. 6G, in some embodiments, the structure shown in FIG. 6F is flipped over and attached to a tape (not shown) (e.g., a dicing tape) supported by a frame (not shown), and a carrier substrate de-bonding operation is performed to detach (de-bond) the carrier substrate 101 from the first RDL 130. In some embodiments, the de-bonding includes projecting a light such as a laser light or a UV light on the release layer so that the release layer decomposes under the heat of the light and the carrier substrate 101 can be removed. Accordingly, a semiconductor package structure 100a, including a stand-alone inductor, is obtained

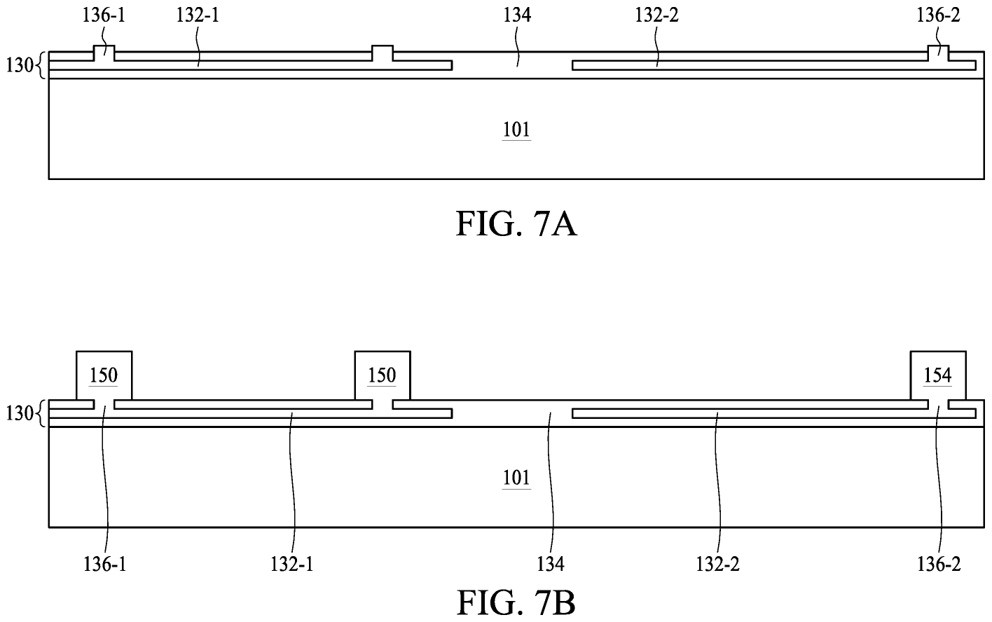

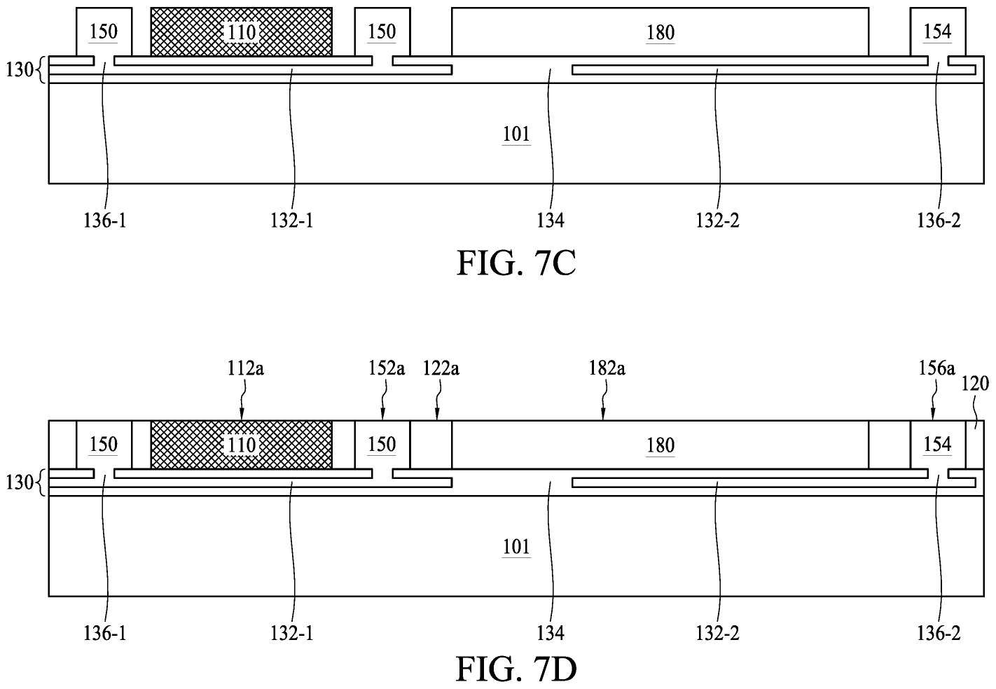

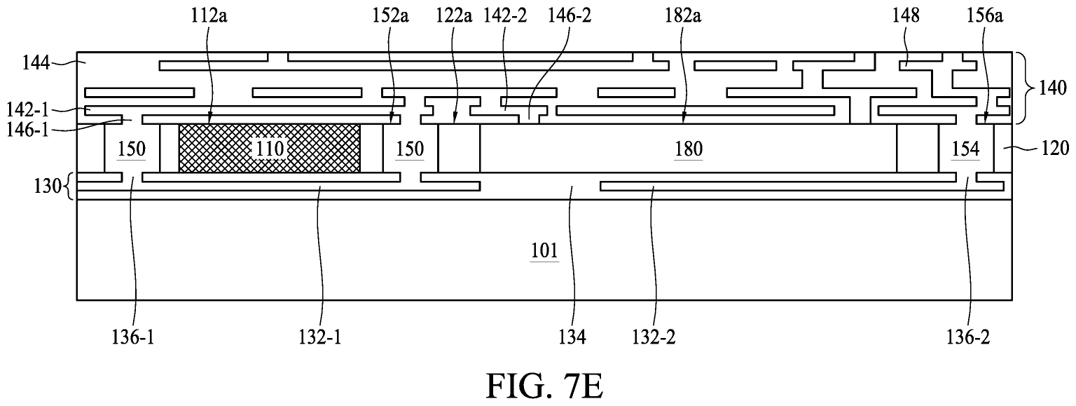

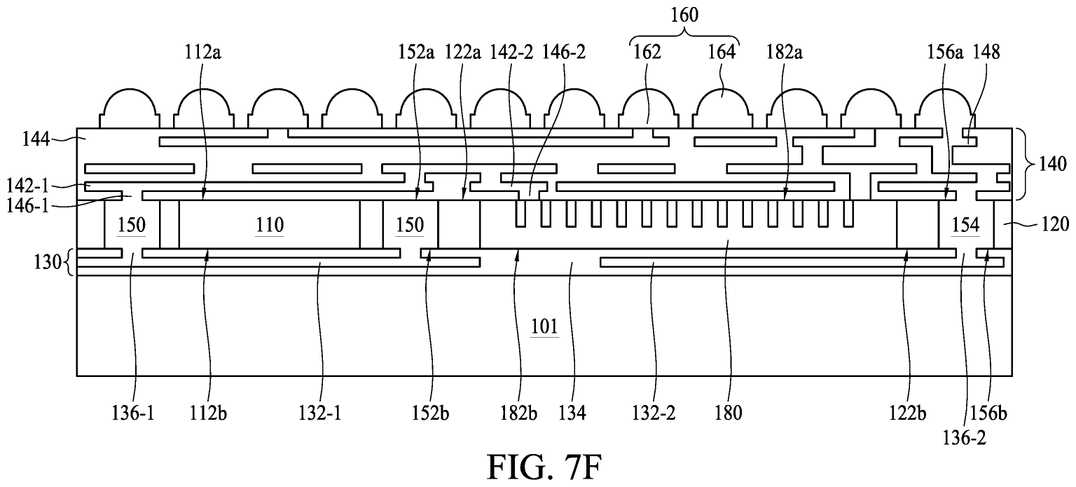

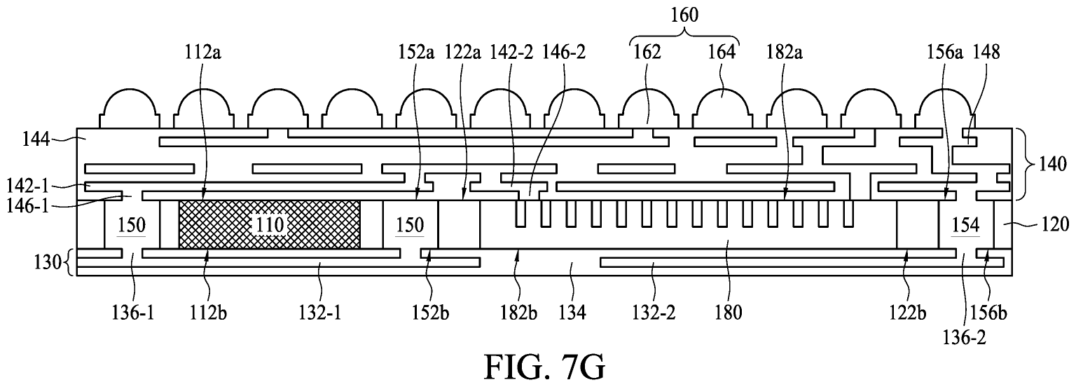

Please refer to FIGS. 7A to 7G, which are schematic drawings illustrating stages of the method for forming a semiconductor structure 20 according to aspects of the present disclosure. It should be noted that same elements in FIGS, 2, 3 and 7A to 7G may include same materials and are indicated by the same numerals; therefore, repeated descriptions are omitted for brevity.

Referring to FIG. 7A, in some embodiments, a first RDL 130 is formed on a carrier substrate 101 in operation 201. In some embodiments, the carrier substrate 101 is received, and a release layer (not shown) may be formed on the carrier substrate 101. In such embodiments, the first RDL 130 may be formed on the release layer.

The first RDL 130 includes a plurality of conductive lines 132-1, 132-2 and a plurality of connecting vias 136-1, 136-2 disposed in a multi-layered dielectric layer 134. As shown in FIG. 7A, the first RDL 130 may include one layer of the conductive lines 132-1, 132-2 and one layer of the connecting vias 136-1, 136-2 in the multi-layered dielectric layer 134. However, in other embodiments, the first RDL 130 may include any number of layers of conductive lines and connecting vias. The connecting vias 136-1 are coupled to the conductive lines 132-1, and the connecting vias 136-2 are coupled to the conductive lines 132-2, as shown in FIG. 7A. In some embodiments, the conductive lines 132-1 and 132-2 are electrically isolated from each other, but the disclosure is not limited thereto. The electrical connection between the conductive lines 132-1 and 132-2 may vary in accordance with different product designs.

Referring to FIG. 7B, a plurality of through vias 150, 154 are formed over the first RDL 130. In some embodiments, the through vias 150 are coupled to the conductive lines 132-1 through the connecting vias 136-1, and the through via 154 is coupled to the conductive lines 132-2 through the connecting vias 136-2.

Referring to FIG. 7C, a magnetic core 110 is attached over the first RDL 130 in operation 203. In some embodiments, one or more dies 180 are attached over the first RDL 130 before or after the attaching of the magnetic core 110. In some embodiments, the magnetic core 110 and the die 180 are adhered to the first RDL 130 by an adhesive layer (not shown), but the disclosure is not limited thereto. It should be noted that a number of the die being attached on the first RDL 130 may vary in accordance with different product designs For example, the die 180 and a die 190 may be attached on the first RDL 130, though not shown in FIGS. 7C to 7G.

Referring to FIG. 7D, a molding 120 is formed over the first RDL 130 to surround the through vias 150, 154, the magnetic core 110 and the die 180 in operation 204. In some mbodiments, a grinding operation may be performed on the molding 120 to expose first via surfaces 152a of the through vias 150 and a first via surface 156a of the through via 154. In some embodiments, a first core surface 112a of the magnetic core 110 and a first die surface 182a of the die 180 are also exposed after the grinding. In some embodiments, the first via surfaces 152a of the through vias 150, the first via surface 156a of the through via 154, the first core surface 112a of the magnetic core 110, a first molding surface 122a of the molding 120 and a first die surface 182a of the die 180 are aligned with (i.e., coplanar with) each other after the grinding. As mentioned above, the first die surface 182a of the die 180 may be an active surface. Therefore, the first RDL 130 is referred to as a back-side RDL.

Referring to FIG. 7E, in some embodiments, a second RDL 140 is formed over the molding 120, the magnetic core 110, the die 180 and the through vias 150 in operation 205. The second RDL 140 includes a plurality of conductive lines 142-1, 142-2 and a plurality of connecting vias 146-1, 146-2 disposed in a multi-layered dielectric layer 144. In some embodiments, because the second RDL 140 is formed aver the active surface of the die 180, the second RDL 140 is referred to as a front-side RDL. As shown in FIG. 7E, the second RDL 140 may include one layer of the conductive lines 142-1, 142-2 and one layer of the connecting vias 146-1, 146-2 in the multi-layered dielectric layer 144. Further, the second RDL 140 may include overlying conductive lines 148 and connecting vias electrically connected to or electrically isolated from the conductive lines 142-1, 142-2, In some embodiments, the conductive lines 142-1 are electrically connected to the through vias 150 by the connecting vias 146-1, and the conductive lines 142-2 are electrically connected to the through via 154 by the connecting vias 146-2.

Referring to FIG. 7F, in some embodiments, a plurality of external connectors 160 are formed over the second RDL 140. The external connectors 160 are formed on an exterior side of the second RDL 140. In some embodiments, each external connector 160 includes a pad 162 and a conductive connector 164 over the pad 162.

Referring to FIG. 7G, in some embodiments, the structure shown in FIG. 7F is flipped over and attached to a tape (not shown) supported by a frame (not shown), and a carrier substrate de-bonding operation is performed to detach (de-bond) the carrier substrate 101 from the first RDL 130. In some embodiments, the de-bonding includes projecting a light such as a laser light or a UV light on the release layer so that the release layer decomposes under the heat of the light and the carrier substrate 101 can be removed. Accordingly, a semiconductor package structure 100b is obtained.

The present disclosure therefore provides a semiconductor package structure including a 3D solenoid inductor and a method for forming the same. The 3D solenoid inductor may include a permanent magnetic core such that a higher inductance is obtained. The 3D solenoid includes a magnetic core encircled by a coil formed of the conductive lines in a back-side RDL, conductive lines in a front-side RDL, and through vias. By using magnetic cores of different sizes and/or shapes, permeability may be modified to meet different product requirements.

According to one embodiment of the present disclosure, a semiconductor package structure is provided. The semiconductor package structure includes a magnetic core, a molding surrounding the magnetic core, a first RDL under the magnetic core, a second RDL over the magnetic core, and a plurality of through vias in the molding, The magnetic core has a first core surface and a second core surface opposite to the first core surface. The molding has a first molding surface and a second molding surface opposite to the first molding surface. The first molding surface is substantially aligned with the first core surface, and the second molding surface is substantially aligned with the second core surface. The first RDL includes a plurality of first conductive lines. The second RDL includes a plurality of second conductive lines. The through vias are coupled to the first conductive lines and the second conductive lines to form a coil surrounding the magnetic core.

According to one embodiment of the present disclosure, a semiconductor package structure is provided. The semiconductor package structure includes a die, a magnetic core adjacent to the die, a molding surrounding the die and the magnetic core, a first RDL, a second RDL, and a plurality of first through vias in the molding. The first RDL is under the die, the magnetic core and the molding, and the second RDL is over the die, the magnetic core and the molding. The first RDL includes a plurality of first conductive lines under the magnetic core, and the second RDL includes a plurality of second conductive lines over the magnetic core. The first through vias are coupled to the first conductive line and the second conductive lines to form a coil surrounding the magnetic core.

According to one embodiment of the present disclosure, a method for forming a semiconductor package structure is provided. The method includes following operations. A first RDL is formed over a carrier substrate. The first RDL includes a plurality of first conductive lines in a same level. A plurality of first through vias are formed over the first RDL. A magnetic core is attached over the first RDL. A molding is formed over the first RDL to surround the first through vias and the magnetic core. A second RDL is formed over the molding, the magnetic core and the first through vias. The second RDL includes a plurality of second conductive lines. The first conductive lines, the first through vias and the second conductive lines are coupled to form a coil surrounding the magnetic core.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure comprising:
a magnetic core having a first core surface and a second core surface opposite to the first core surface;
a molding surrounding the magnetic core, wherein the molding has a first molding surface and a second molding surface opposite to the first molding surface, the first molding surface is substantially aligned with the first core surface, and the second molding surface is substantially aligned with the second core surface;
a first redistribution layer (RDL) comprising a plurality of first conductive lines under the magnetic core;
a second RDL comprising a plurality of second conductive lines over the magnetic core; and
a plurality of through vias in the molding, wherein the through vias are coupled to the first conductive lines and the second conductive lines to form a coil surrounding the magnetic core.

2. The semiconductor package structure of claim 1, wherein each of the through vias has a first via surface and a second via surface opposite to the first via surface, the first via surface is substantially aligned with the first core surface and the first molding surface, and the second via surface is substantially aligned with the second core surface and the second molding surface.

3. The semiconductor package structure of claim 1, wherein the first RDL further comprises a plurality of first connecting vias coupling the first conductive lines to the through vias, and the second RDL further comprises a plurality of second connecting vias coupling the second conductive lines to the through vias.

4. The semiconductor package structure of claim 1, wherein the first conductive lines are in a same level, and the second conductive lines are in a same level.

5. semiconductor package structure of claim 1, further comprising a plurality of external connectors disposed over the second RDL.

6. The semiconductor package structure of claim 1, wherein the magnetic core comprises a permanent magnetic core.

7. A semiconductor package structure, comprising:
a die;
a magnetic core adjacent to the die;
a molding surrounding the die and the magnetic core;
a first RDL under the die, the magnetic core and the molding, wherein the first RDL comprises a plurality of first conductive lines under the magnetic core;
a second RDL over the die, the magnetic core and the molding, wherein the second RDL comprises a plurality of second conductive lines over the magnetic core; and
a plurality of first through vias in the molding coupling the first conductive lines to the second conductive lines to form a coil surrounding the magnetic core.

8. The semiconductor package structure of claim 7, wherein the first RDL further comprises at least a third conductive line electrically connected to the die, and the second RDL further comprises at least a fourth conductive line electrically connected to the third conductive line,

9. The semiconductor package structure of claim 8, further comprising at least a second through via in the molding, wherein the second through via electrically connects the third conductive line to the fourth conductive line.

10. The semiconductor package structure of claim 7, further comprising a plurality of external connectors disposed over the second RDL and electrically connected to the die,

11. The semiconductor package structure of claim 7, wherein a thickness of the die, a thickness of the magnetic core, and a thickness of the molding are substantially same.

12. The semiconductor package structure of claim 7, wherein the die is electrically connected to the coil.

13. The semiconductor package structure of claim 7, wherein the die is electrically isolated from the coil.

14. A method for forming a semiconductor package structure, comprising:
forming a first RDL over a carrier substrate, wherein the first RDL comprises a plurality of first conductive lines in a same level;
forming a plurality of first through vias over the first RDL;
attaching a magnetic core over the first RDL;
forming a molding over the first RDL to surround the first through vias and the magnetic core; and
forming a second RDL over the molding, the magnetic core and the first through vias, wherein the second RDL comprises a plurality of second conductive lines in a same level,
wherein the first conductive lines, the first through vias and the second conductive lines are coupled to form a coil surrounding the magnetic core.

15. The method of claim 14, wherein the first RDL further comprises at least a third conductive line, and the second RDL further comprises at least a fourth conductive line.

16. The method of claim 15, further comprising forming at least a second through via over the first RDL simultaneously with the forming of the first through vias, wherein the second through via electrically connects the third conductive line to the fourth conductive line.

17. The method of claim 15, further comprising attaching at least a die over the first RDL, wherein the die is electrically connected to the fourth conductive line.

18. The method of claim 17, wherein the die is electrically connected to the coil.

19. The method of claim 17, wherein the die is electrically isolated from the coil.

20. The method of claim 14, further comprising forming a plurality of external connectors over the second RDL.
